(19) United States
(12) Patent Application Publication
(10) Pub. No.: US 2009/0073651 A1
(43) Pub. Date: Mar. 19, 2009

(54) Fastening mechanism

(75) Inventors: Tiger Hu, Shanhai City (CN); Tsai-Kuei Cheng, Taipei City (TW)

Correspondence Address: Edwards Angell Palmer & Dodge LLP, P.O. Box 55874, Boston, MA, 02205, US

(73) Assignee: Inventec Corporation, Taipei City (TW)

(21) Appl. No.: 12/006,542

(22) Filed: Jan. 3, 2008

(30) Foreign Application Priority Data
Sep. 7, 2007 (TW) 096133504

(51) Int. Cl. G06F 1/16; H05K 7/00

(52) U.S. Cl. 361/679.58

(57) ABSTRACT

A fastening mechanism for fastening a module and a second module in the housing of an electronic device is disclosed. The fastening mechanism includes a lid body and a positioning member disposed in the housing. The first module is fixed in the housing by the lid body and the lid body is fastened by the positioning member, which is coupled to and overlaps the second module on the lid body, thereby using a shared common space for concurrently holding the lid body, the first module and the second module in place to save the layout space of the electronic device.

### BACKGROUND OF THE INVENTION

1. Field of the Invention

The present invention relates to fastening mechanisms, and more particularly, to a fastening mechanism for an electronic equipment.

2. Description of the Related Art

In the rapid development of internet, servers used for internet are well-developed, and requirements for a power supply of a server are growing.

Conventional power supplies for servers cannot meet the requirements of energy consumption, especially for middle-scale and high-end servers. Currently, the ATX power supply is commonly a standard power supply for PC and servers. The ATX power supply includes single and redundant power supplies. The single power supply, which has low power consumption, is mainly used for PCs and low-end servers, whereas the redundant power supply is commonly used in middle-scale and high-end server equipment to ensure its reliability in supplying power without failure, as mentioned above.

However, the redundant power supply consists of multiple single power supplies and thus occupies more space than one single power supply in a server unit. Moreover, a motherboard is usually installed in the server near the area surrounding the power supply unit, which necessitates the use of respective fastening mechanisms for fastening both the power supply unit and the motherboard in respective positions, thus requiring more space for accommodating respective fastening mechanisms in the server. Hence, it leads to an inconvenient and inefficient installation due to the limited space in a server.

In an effort to solve the problem mentioned above, a common solution is to modify the housing to enlarge its accommodating space, or alternatively, to change the volume of power supply or the size of the motherboard so as to be accommodated in the housing. However, the approach to modify the housing is strictly limited by standard specifications such as SSI and ATX and thus it is difficult to realize such approach. And even if it can be realized, the perspective on its marketablity is also doubtful. Similarly, the alteration of existing motherboards is not promising either and the perspective in designing new redundant-typed power supplies for such purposes will only incur more costs and does not provide industrial applicability to solve the problem.

Therefore, it is desirable and beneficial to provide a novel mechanism for fastening power supply in a server that can overcome the drawbacks of conventional techniques mentioned above.

### SUMMARY OF THE INVENTION

The present invention aims to eliminate the aforementioned drawbacks, and, as such, an objective of the present invention is to provide an effective fastening mechanism for an electronic equipment that does not take as much space as required in the prior art and thus can save the inner layout space of the electronic equipment.

Another objective of the present invention is to provide a fastening mechanism for an electronic equipment that facilitates installation and thus increases efficiency.

In order to achieve the above and other objectives, the present invention provides a fastening mechanism for fastening a first module and a second module into a housing of an electronic device, wherein the second module comprises a plurality of first engaging portions to be coupled with the housing of the electronic device by means of corresponding engaging members. The fastening mechanism includes an accommodating portion for accommodating the first module, and a lid body having an extending portion overlapping the housing, and a plurality of gourd-shaped openings linearly aligned and formed in the extending poriton for corresponding to first engaging portions; and a plurality of positioning members corresponding in number to the gourd-shaped openings. The positioning members each includes a penetrating portion connected to the housing for correspondingly penetrating through each of the gourd-shaped openings, an expanding step portion disposed on the penetrating portion, correspondingly coupled to each of the extending portions and overlapping the second module, and a plurality of second engaging portions corresponding to first engaging portions and penetrating through the expanding step portion and the penetrating portion, thereby allowing the engaging members to penetrate through the first and second engaging portions and concurrently fasten the lid body, the first and second modules within the housing of the electronic equipment to save layout space thereof.

In the fastening mechanism of the present invention, the extending portion includes a folding fringe disposed at one side of the lid body. The thickness of the folding fringe may be smaller than the height of the penetrating portion. The gourd-shaped openings include relatively small aperatures and relatively large aperatures, which are interconnected and aligned in a linear manner. The penetrating portion of the positioning member may be smaller than the small aperture, and the size of the expanding step portion may be larger than the small aperature but smaller than the large aperture. In one embodiment, the engaging member may include a screw head and the first engaging portion may be a via opening for accommodating the screw head, wherein the head of the screw head is larger than the via opening for suppressing the second module. Preferably, the penetrating poriton is a tube and the second engaging portion is a screw bore disposed in the inner wall of the tube.

In addition, the fastening mechanism may further include an insulation body disposed between the second module and the lid body and thereby short circuits can be prevented. The lid body includes an accommodating portion for accommodating the first module, and may further include a plurality of cooling openings for facilitating effective heat dissipation.

Compared to the prior art techniques, the present invention provides a lid body attached to the housing of the electronic equipment, wherein the lid body includes an accommodating portion for receiving a first module and includes an extending portion overlapping a second module and fastened to the housing by means of a positioning member, such that the lid body, the first and second modules can be concurrently secured in position within the housing to save the layout space, thereby providing a simple structure for easy installation and improving assembly efficiency.

In addition, the fastening mechanism of the present invention has a simple structure, is easy to be manufactured and has low cost.

### BRIEF DESCRIPTION OF THE DRAWINGS

The present invention can be more fully understood by reading the following detailed description of the preferred embodiments, with reference made to the accompanying drawings, wherein:

FIG. 1 is a schematic view showing the fastening mechanism according to the first preferred embodiment of the present invention;

FIG. 2 is a cross-sectional view showing the installation of the lid body and a first module depicted in FIG. 1 in the housing;

FIGS. 3A and 3B are enlarged perspective views showing the motion of the lid body as depicted in FIG. 2 being positioned within the housing;

FIG. 4A is a cross-sectional view showing the installation of a second module in the housing as depicted in FIG. 2; and

FIG. 4B is a cross-sectional view showing the installation of the lid body, the first module and the second module in the housing as depicted in FIG. 4A by means of the engaging members.

### DETAILED DESCRIPTION OF THE PREFERRED EMBODIMENTS

The following illustrative embodiments are provided to illustrate the disclosure of the present invention, these and other advantages and effects can be apparently understood by persons skilled in the art after reading the disclosure of this specification. The present invention can also be performed or applied by other different embodiments. The details of the specification may be on the basis of different points and applications, and numerous modifications and variations can be devised without departing from the spirit of the present invention.

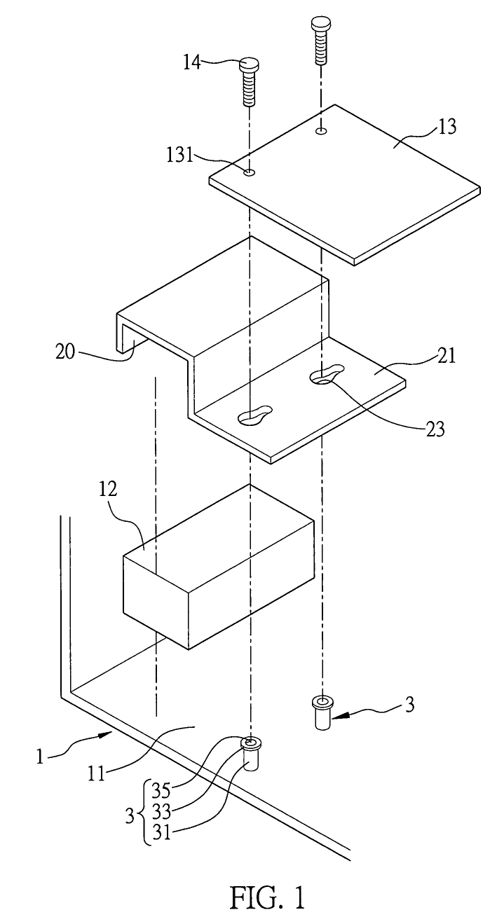

Please refer to FIG. 1, which is a schematic view showing the fastening mechanism according to the first preferred embodiment of the present invention. As illustrated, the fastening mechanism is applicable for fastening a first module 12 and a second module 13 to the housing 11 of an electronic device 1, wherein the second module 13 includes a plurality of first engaging portions 131 to be accommodated in the housing 11 of the electronic device 1 by a plurality of corresponding engaging members 14. The fastening mechanism includes a lid body 2 and a plurality of positioning members 3.

In this embodiment, the electronic device 1 is a server and the housing 11 is the housing of the server, the first module 12 is a power supply and the module 13 is a motherboard. Note that the structures of the housing 11, the first module 12, and the second module 13 can vary in other embodiments depending on the actual requirements. Similarly, the fastening mechanism of the present invention is applicable for fastening various modules and electronic components to the housing of an electronic device and is not limited to the ones disclosed herein.

The lid body 2 includes an accommodating portion 20 for accommodating the first module 12, an extending portion 21 overlapping the housing 11, and a plurality of gourd-shaped openings 23 disposed in the extending portion 21 and each corresponding to first engaging portions 131 respectively. In this embodiment, the lid body 2 has a cross-section in the shape of “ ” in which the accommodating portion 20 is formed for receiving the first module 12, and one side of the “ ” shaped structure is parallel to a perpendicular side wall of the housing 11. The extending portion 21 is connected to the accommodating portion 20 and is parallel to a bottom panel of the housing 11. Each of the gourd-shaped openings 23 is formed with a plurality of interconnected small apertures and large apertures aligned in a linear manner. Note that a pair of gourd-shaped openings, but not limited to, are formed in this preferred embodiment. Further, a plurality of stub bores may be disposed on a perpendicular side wall of the housing 11 (not shown), thereby locking the screws into the screw bores from outside of the housing 11 to fasten the lid body 2 to the side wall of the housing 11. Alternatively, the lid body 2 and the housing 11 may be fastened together by positioning members other than the ones disclosed herein.

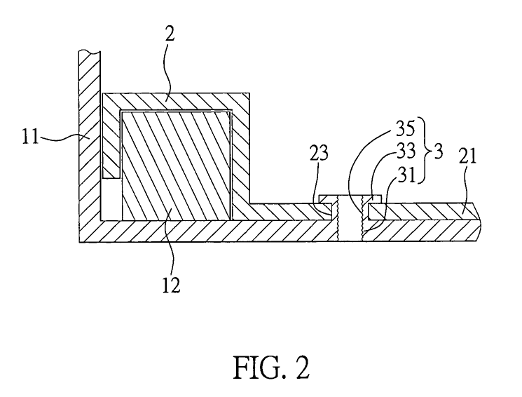

Referring to FIG. 2, the accommodating portion 20 formed in the lid body 2 and the housing 11 can limit the motion of the first module 12 (i.e. the power supply) in all directions, and the lid body 2 can limit the mothion of the first module 12 in three directions. In other embodiments, the part of the lid body 2 corresponding to a rear side of the first module 12 may optionally include an inward blocking piece (not shown), while another idential blocking piece (not shown) may be provided at a position corresponding to the surface of the housing 11, thereby limiting the motion of the rear side of the lid body 2. Since disposal of a blocking piece for limiting motion is a common well-known technique, there will be no further description provided herein for the sake of brevity.

The positioning members 3 are disposed on the housing 11 and correspond to the gourd-shaped openings respectively. In this embodiment, each of the positioning members 3 is disposed on a bottom panel of the housing 11 and includes a penetrating portion 31 connected to the housing 11 for penetrating through each of gourd-shaped openings 23 respectively, an expanding step portion 33 disposed on the penetrating portion 31, correspondingly coupled to each of the extending portions 21 and overlapping the second module 13, and a plurality of second engaging portions 35 corresponding to first engaging portions 131 and each penetrating through the expanding step portion 33 and the penetrating portion 31. In this embodiment, the penetrating portion 31 is a tube, and the expanding step portion 33 is adapted to penetrate through gourd-shaped openings 23 to fasten the lid body 2. The second engaging poriton 35 may be, but not limited to, screw bores disposed in an inner wall of the penetrating portion 31 for correspondingly positioning the gourd-shaped openings 23 and for allowing the engaging member 14 to penetrate through the first and second engaging portions 131, 35 and concurrently fasten the lid body 11, the first and second modules 12, 13 within the housing 11 to save layout space thereof.

In one aspect of the invention, the extending portion 21 comprises a folding fringe disposed at one side of the lid body 2. The thickness of the folding fringe may be smaller than the height of the penetrating portion 31. The gourd-shaped openings 23 each includes a plurality of interconnected small and large apertures aligned in a linear manner. The penetrating portion 31 of the positioning member 3 may be smaller than the small aperture of the gourd-shaped openings 23 and the expanding step portion 33 may be larger than the small aperature but smaller than the large aperture of the gourd-shaped openings 23. In one embodiment, the engaging member 14 may include a screw head, the first engaging portion 131 of the second module 13 may be a via opening for accommodating the screw head, and the head of the screw head is larger than the via opening for supressing the second module 13.

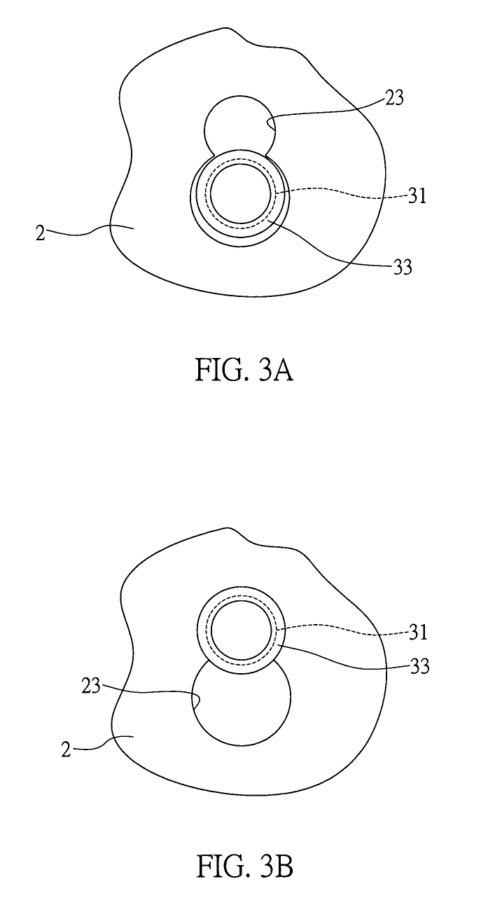

As shown in FIG. 2, the first module 12 is installed in the housing 11, and as depicted in FIG. 3A, the first module 12 is covered by the lid body 2, wherein the expanding step portion 33 of the positioning member 3 passes through the large aperture of the gourd-shaped opening 23, the penetrating portion 31 of the positioning member 3 is positioned in the large aperture of the gourd-shaped opening 23, in which the diameter of the large aperture of the gourd-shaped opening 23 is larger than that of the expanding step portion 33 of the positioning member 3, and the lid body 2 is then moved toward the direction shown by an arrow A in FIG. 3 with respect to the positioning member 3 until the positioning member 3 is received in the small aperture of the gourd-shaped opening 23, in which the diameter of the small aperture of the gourd-shaped opening 23 is larger than that of the expanding step portion 33 of the positioning member 3, thereby preventing detachment of the lid body 2 from the housing 11, as shown in FIG. 2.

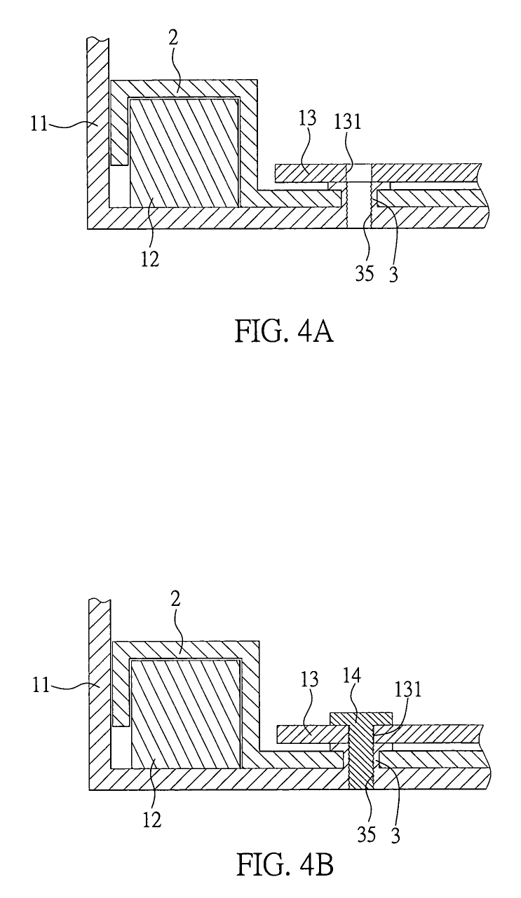

Subsequently, as shown in FIG. 4A, the second module 13 (i.e. the motherboard) is disposed in a corresponding position of the housing 11, and the first engaging portions 131 of the second module 13 are each correspondingly connected with the second engaging portions 35 respectively. As shown in FIG. 4B, the engaging member 14 such as a pair of screws are each locked into both the first engaging portions 131 and the second engaging portion 35 respectively, thereby concurrently fastening the lid body 2, the first module 12 and the second module 14 within the housing 11. In other words, the invention effectively utilize a common space to optimize the concurrent fastening of the lid body 2, the first module 12 and the second module 14 within the housing 11, such that the layout space in the server can be preserved and the need to use different mechanisms for respectively fastening the first module 12 and the second module 13 can be eliminated, thereby simplifying steps of installation and increasing assembly efficiency.

Note that the first engaging portions 131 include, but not limited to screw bores disclosed herein. If the gourd-shaped openings 23 are used, there is no tool required for disassembly, that is, by pushing the lid body 2, the positioning member 3 slides from a large aperture thereof into an interconnected small aperture of the gourd-shaped opening 23 and vise versa.

Further, the lid body 2 may be a metallic member, and an insulation body or other buffering material such as mylar may be disposed between the second module 13 and the lid body 2 to prevent contacts between the second module 13 and the lid body 12 which result in short circuits. The lid body 2 may further include a plurality of cooling openings to facilitate effective heat dissipation. In other embodiments, the positioning member 3 may be coated with an insulation material such as mylar to prevent short circuits.

Compared to the conventional techniques, the present invention provides a lid body attached to the housing of an electronic equipment, wherein the lid body includes an accommodating portion for accommodating a first module therein, and an extending portion, overlapping a second module and fastened to the housing by means of one or more positioning members, such that the lid body, the first and second modules can be concurrently fastened within the housing to save the layout space thereof, thereby providing a simple structure for easy installation and improving assembly efficiency.

While the illustrative embodiments are provided in the above description, such is for illustration of principles and functions of the present invention only and it is not to be construed restrictively. Modifications and variations of the present invention that will be obvious to those skilled in the art are to be covered by the following claims.

What is claimed is:

1. A fastening mechanism for fastening a first module and a second module into a housing of an electronic device, wherein the second module comprises a plurality of first engaging portions to be coupled with the housing of the electronic device by means of corresponding engaging members, the fastening mechanism comprising:
a lid body having an accommodating portion for accommodating the first module, an extending portion overlapping the housing, and a plurality of gourd-shaped openings linearly aligned and formed in the extending portion for corresponding to the first engaging portions; and
a plurality of positioning members corresponding in number to the gourd-shaped openings, wherein the positioning members each comprises a penetrating portion connected to the housing for correspondingly penetrating through the gourd-shaped openings, an expanding step portion disposed on the penetrating portion, correspondingly coupled to the extending portions and overlapping the second module, and a plurality of second engaging portions corresponding to the first engaging portions and penetrating through the expanding step portion and the penetrating portion, thereby allowing the engaging members to penetrate through the first and second engaging portions and concurrently fasten the lid body, the first and second modules within the housing of the electronic equipment.

2. The fastening mechanism according to claim 1, wherein the extending portion comprises a folding fringe disposed at one side of the lid body.

3. The fastening mechanism according to claim 2, wherein the folding fringe has a thickness smaller than the height of the penetrating portion.

4. The fastening mechanism according to claim 1, wherein the gourd-shaped openings comprise a plurality of relatively small and relatively large aperatures, which are interconnected and aligned in a linear manner.

5. The fastening mechanism according to claim 4, wherein the penetrating portion of the positioning member is smaller than the relatively small aperture, and the size of the expanding step portion is larger than the relatively small aperture but smaller than the relatively large aperture.

6. The fastening mechanism according to claim 1, wherein the engaging member comprises a screw head, the first engaging portion is a via opening for accommodating the screw head, and the head of the screw head is larger than the via opening for suppressing the second module.

7. The fastening mechanism according to claim 1, wherein the penetrating poriton is a tube and the second engaging portion is a screw bore disposed in an inner wall of the tube.

8. The fastening mechanism according to claim 1, further comprising an insulation body disposed between the second module and the lid body.
